(19) United States
(12) Patent Application Publication
(10) Pub. No.: US 2019/0326205 A1
(43) Pub. Date: Oct. 24, 2019

(54) CHIP PACKAGE

(71) Applicant: PixArt Imaging Inc., Hsin-Chu City (TW)

(72) Inventors: Peng-Sheng Chen, Hsin-Chu City (TW); Jui-Te Chiu, Hsin-Chu City (TW)

(21) Appl. No.: 15/957,930

(22) Filed: Apr. 20, 2018

(51) Int. Cl. H01L 23/498; G06F 3/03

(52) U.S. Cl. CPC H01L 23/49805; G06F 3/0317

(57) ABSTRACT

A chip package with at least eight pins includes a main body, seven first pins and a second pin. An integrated circuit is disposed inside the main body. The seven first pins are electrically connected with the integrated circuit and configured to provide specific functions. The second pin is electrically connected with the integrated circuit and disposed adjacent by some of the seven first pins. The second pin is a free pin and unconnected with a passive component. The second pin is applied for empty connection, switch of detection accuracy, printing actuation or page turning.

### BACKGROUND OF THE INVENTION

### 1. Field of the Invention

The present invention relates to a chip package, and more particularly, to a chip package without utilization of any passive component.

### 2. Description of the Prior Art

With an update of the conventional electronic apparatus, the circuit system of the new-generation electronic apparatus may be different from the former-generation electronic apparatus, so that circuit arrangement of a chip package applied to electronic apparatus may be coupled with a passive component according to electrical characteristics of the chip circuit. The passive component can be, but not limited to, a resistor, a capacitor and an inductor. For example, while the new-generation electronic apparatus has an extra light emitting diode, the conventional chip package has to be additionally matched with an external resistor for current limit and circuit protection. The additional external passive component is electrically connected with a pin of the chip package, so that the conventional chip package has low compatibility and is difficult to expand new function. Thus, design of a new-typed chip package without utilization of any passive component is an important issue in the related industry.

### SUMMARY OF THE INVENTION

The present invention provides a chip package without utilization of any passive component for solving above drawbacks.

According to the claimed invention, a chip package with at least eight pins includes a main body, seven first pins and a second pin. An integrated circuit is disposed inside the main body. The seven first pins are electrically connected with the integrated circuit and configured to provide specific functions. The second pin is electrically connected with the integrated circuit and disposed adjacent by some of the seven first pins. The second pin is a free pin and unconnected with a passive component. The second pin is applied for empty connection, switch of detection accuracy, printing actuation or page turning.

According to the claimed invention, the chip package further includes three third pins and a fourth pin electrically connected with the integrated circuit. The three third pins are configured to provide the specific functions, and the fourth pin is the free pin and unconnected with the passive component. The fourth pin is applied for empty connection, switch of detection accuracy, printing actuation or page turning. The second pin and the fourth pin are situated on a side of the main body, and there are six pins situated on the said side. The second pin is situated furthest to an edge of a six-pin arrangement, and the fourth pin is situated at a middle of remained five pins of the six-pin arrangement.

The entire scheme of the electronic product is preferably unvaried to keep system stability, but the circuit package may be adjusted to satisfy its circuit characteristics in accordance with an update of the electronic product. For the new-generation electronic product, a conventional chip package may have to be integrated with the external passive component (such as the resistor, the capacitor and the inductor) in order to match design's demand of the updated electronic product. The chip package of the present invention can have the built-in passive component optionally and does not need the extra external passive component; therefore, the chip package has preferred compatibility for the former and updated electronic product and can utilize the second pin and the fourth pin located on designated positions for newly-added functions, such as at least one of idling, the empty connection, the switch of detection accuracy, the printing actuation and the page turning.

These and other objectives of the present invention will no doubt become obvious to those of ordinary skill in the art after reading the following detailed description of the preferred embodiment that is illustrated in the various FIGURES and drawings.

### BRIEF DESCRIPTION OF THE DRAWINGS

The FIGURE is a diagram of a chip package according to an embodiment of the present invention.

### DETAILED DESCRIPTION

Please refer to the FIGURE, which is a diagram of a chip package 10 according to an embodiment of the present invention. The chip package 10 can include a main body 12 and several pins, and the pins are electrically connected with an integrated circuit (not shown in the FIGURE) disposed inside the main body 12. The chip package 10 may have at least eight pins; however, the present invention provides an example of the chip package 10 having twelve pins for preferred application. The said twelve pins include seven first pins 14, 16, 18, 20, 22, 24 and 26, a second pin 28, three third pins 30, 32 and 34, and a fourth pin 36. The first pins 14, 16, 18, 20, 22, 24 and 26 and the third pins 30, 32 and 34 are configured to provide predefined specific functions.

For instance, as the chip package 10 is applied for a mouse of a personal computer, the specific function of the first pin 14 can be used for input of a button left key, and the specific function of the first pin 16 can be used for control of a light unit (such like a light emitting diode), and the specific function of the first pin 18 can be used for ground connection, and the specific function of the first pin 20 can be used for connecting a power supply, and the specific function of the first pins 22 and 24 can be respectively used for a first data transmission of a universal serial bus and a second data transmission of the universal serial bus (or respectively for the PS/2 mouse clock line and the PS/2 mouse data line), and the specific function of the first pin 26 can be used for input of a button right key; furthermore, the specific function of the third pin 30 can be used for input of a button middle key, and the specific function of the third pins 32 and 34 can be used for input of Z-axes.

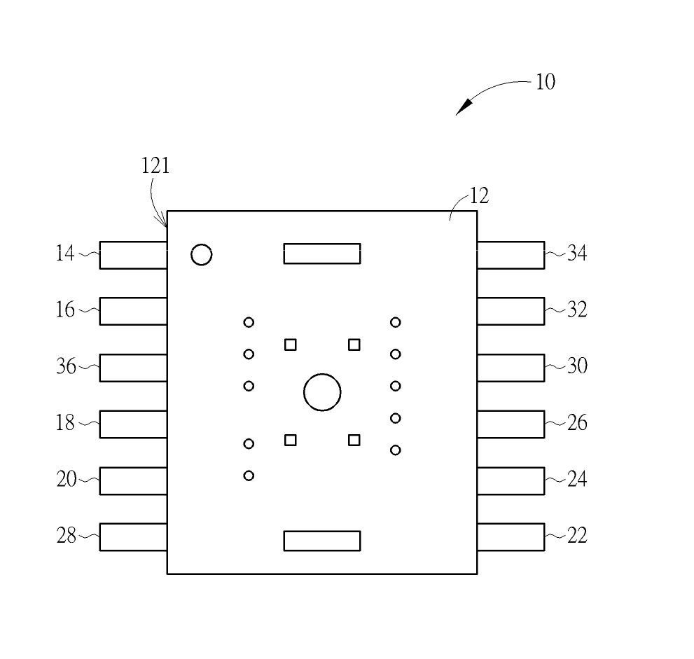

As shown in FIG. 1, the second pin 28 and the fourth pin 36 are situated on a side 121 of the main body 12, and there are six pins (further including the first pins 14, 16, 18 and 20) situated on the side 121 of the main body 12. The second pin 28 is situated furthest to an edge of a six-pin arrangement on the side 121, which means the second pin 28 is located on an outer margin; the fourth pin 36 is situated at a middle of remained five pins of the six-pin arrangement, which means the fourth pin 36 is located between the first pins 14 and 16 and the first pins 18 and 20. Arrangement and circuit characteristics of the second pin 28 and the fourth pin 36 are predefined and unable to connect with the external passive component. In the embodiment of the present invention, the second pin 28 and the fourth pin 36 are free pins and unconnected with any passive component. Therefore, the second pin 28 and the fourth pin 36 can be used for, but not limited to, empty connection, switch of detection accuracy, printing actuation or page turning while the chip package 10 is as applied for the mouse of the personal computer.

An entire scheme of the electronic product is preferably unvaried to keep system stability, but the circuit package may be adjusted to satisfy its circuit characteristics in accordance with an update of the electronic product. For the new-generation electronic product, a conventional chip package may have to be integrated with the external passive component (such as the resistor, the capacitor and the inductor) in order to match design's demand of the updated electronic product. Comparing to the prior art, the chip package of the present invention can have the built-in passive component optionally and does not need the extra external passive component; therefore, the chip package has preferred compatibility for the former electronic product and the updated electronic product and can utilize the second pin and the fourth pin located on designated positions for newly-added functions, such as at least one of idling, the empty connection, the switch of detection accuracy, the printing actuation and the page turning.

Those skilled in the art will readily observe that numerous modifications and alterations of the device and method may be made while retaining the teachings of the invention. Accordingly, the above disclosure should be construed as limited only by the metes and bounds of the appended claims.

1: A chip package with at least eight pins, the chip package comprising:
a main body where inside an integrated circuit is disposed;
seven first pins electrically connected with the integrated circuit and configured to provide specific functions; and
a second pin electrically connected with the integrated circuit and disposed adjacent to at least one of the seven first pins, the second pin being a free pin unconnected with an external passive component;
wherein the chip package is operated without the external passive component.

2: The chip package of claim 1, wherein the second pin is configured to transmit a signal about functions of for switch of detection accuracy, printing actuation or page turning of an external electronic device connected to the chip package.

3: The chip package of claim 1, wherein the chip package is configured for a mouse, the specific functions of the first pins are selected from a group consisting of ground connection, input of a button left key, input of a button right key, control of a lighting unit, power supply, a first data transmission of a universal serial bus, and a second data transmission of the universal serial bus.

4: The chip package of claim 1, wherein the chip package further comprises three third pins and a fourth pin electrically connected with the integrated circuit, the three third pins are configured to provide the specific functions, and the fourth pin is unconnected with an external passive component.

5: The chip package of claim 4, wherein the fourth pin is configured to transmit a signal about functions of switch of detection accuracy, printing actuation or page turning of an external electronic device connected to the chip package.

6: The chip package of claim 4, wherein the second pin and the fourth pin are situated on a side of the main body, and there are six pins situated on the said side.

7: The chip package of claim 4, wherein the second pin is situated furthest to an edge of a six-pin arrangement, and the fourth pin is situated at a middle of remained five pins of the six-pin arrangement.

8: The chip package of claim 4, wherein the chip package is configured for a mouse, the specific functions of the third pins are selected from a group consisting of input of a button middle key and Z-axes.
